(19) United States
(12) Patent Application Publication
(10) Pub. No.: US 2014/0138606 A1
(43) Pub. Date: May 22, 2014

(54) RESISTANCE VARIABLE MEMORY DEVICE

(71) Applicant: SK HYNIX INC., Icheon (KR)

(72) Inventor: Jun-Kyo SUH, Icheon (KR)

(73) Assignee: SK HYNIX INC., Icheon (KR)

(21) Appl. No.: 13/846,536

(22) Filed: Mar. 18, 2013

(30) Foreign Application Priority Data
Nov. 22, 2012 (KR) 10-2012-0133037

(51) Int. Cl. H01L 45/00

(52) U.S. Cl. CPC H01L 45/1253
USPC 257/4

(57) ABSTRACT

Embodiments relate to a resistance variable memory device and a method for forming the same. The resistance variable memory device may include a first electrode, a second electrode spaced apart from the first electrode, a first resistance variable pattern provided over the first electrode and surrounding a lower portion of the second electrode, and a spacer surrounding a sidewall of the first resistance variable pattern. According to embodiments, the resistance variable pattern can be prevented from being damaged in an etching process and an air gap surrounding a portion of the electrode may contribute to improve reliability and an operational speed of the resistance variable memory device.

### CROSS-REFERENCE TO RELATED APPLICATIONS

The present application claims priority of Korean Patent Application No. 10-2012-0133037, filed on Nov. 22, 2012, which is incorporated herein by reference in its entirety.

### BACKGROUND

1. Field

Exemplary embodiments relate to a resistance variable memory device and a method for fabricating the same, and more particularly, to a resistance variable memory device having a resistance variable between two electrodes and a method for fabricating the same.

2. Description of the Related Art

A resistance variable memory uses a switching material whose resistance varies between at least two different resistance states depending on external inputs to store data. The resistance variable memory includes Resistive Random Access Memory (ReRAM), Phase Change RAM (PCRAM), Spin Transfer Torque-RAM (STT-RAM), etc. The resistance variable memory is desirable because it has a simple structure and has good non-volatile characteristics.

For example, ReRAM includes a resistance variable material such as a Perovskite-based material and a transitional metal oxide, and upper and lower electrodes. In the ReRAM, a filament as a current path is created in or disappeared from the resistance variable material, depending on an amount of voltage applied to the electrodes. When the filament as the current path is created, the resistance variable material is at a low resistance state. In contrast, when the filament as the current path disappears, the resistance variable material is at a high resistance state.

FIG. 1 shows a cross-sectional view of a conventional resistance variable memory device.

Referring to FIG. 1, a lower electrode 20 is provided in a manner of passing through an interlayer insulating layer 10. A resistance variable pattern 30 and an upper electrode 40 are formed over the lower electrode 20. Under this conventional device structure, sidewalls (S) of the resistance variable pattern 30 and the upper electrode 40 can be damaged in the course of an etching process. As a result, their properties deteriorate and reliability of a resistance variable memory device is degraded.

### SUMMARY

An embodiment provides a resistance variable memory device having an air gap which surrounds a portion of an electrode to avoid damage to the resistance variable material, and a method for forming such resistance variable memory device. According to embodiments, reliability and operational speed of the resistance variable memory device can be improved.

In an embodiment, a resistance variable memory device may include a first electrode; a second electrode spaced apart from the first electrode; a first resistance variable pattern provided over the first electrode and surrounding a lower portion of the second electrode; and a spacer surrounding a sidewall of the first resistance variable pattern.

In an embodiment, a resistance variable memory device may include a first electrode; a second electrode spaced apart from the first electrode; a first resistance variable pattern provided over the first electrode and surrounding a lower portion of the second electrode; and an air gap surrounding a portion of a sidewall of the second electrode.

In an embodiment, a method for forming a resistance variable memory device may include forming a first electrode over a substrate; forming a sacrificial pattern over the first electrode; forming a spacer surrounding a sidewall of the sacrificial pattern; removing the sacrificial pattern; forming a first resistance variable layer over the substrate where the sacrificial pattern is removed; and forming a second electrode over the first resistance variable layer over the first electrode.

According to various embodiments, a resistance variable pattern is protected from being damaged. In addition, an air gap surrounding a portion of an electrode can improve reliability and an operational speed of a resistance variable memory device.

### BRIEF DESCRIPTION OF THE DRAWINGS

FIG. 1 is a cross-sectional view illustrating a conventional resistance variable memory device and a method for forming the conventional resistance variable memory device.

FIGS. 2A to 12B illustrate a resistance variable memory device according to an embodiment, and a method for forming the resistance variable memory device.

FIG. 13 is a prospective view illustrating a cross point cell array structure.

FIG. 14 is a block diagram illustrating a resistance variable memory device according to an embodiment.

FIG. 15 is a block diagram illustrating a data processing system employing a resistance variable memory device according to an embodiment.

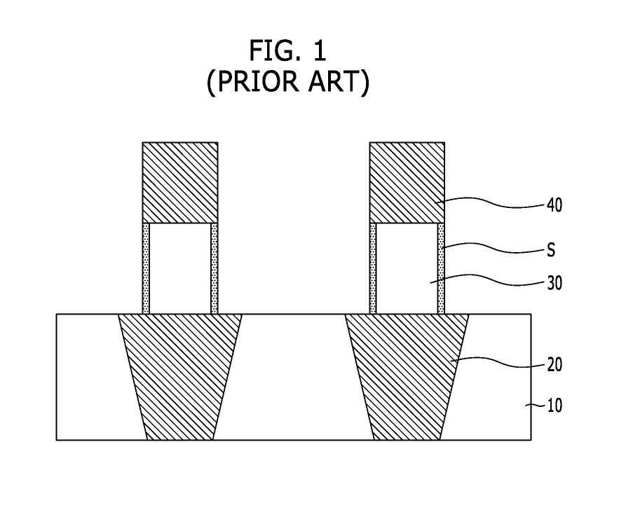

### DETAILED DESCRIPTION

Various embodiments will be described below in more detail with reference to the accompanying drawings. Various embodiments may, however, take different forms and are not limited to the specific embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

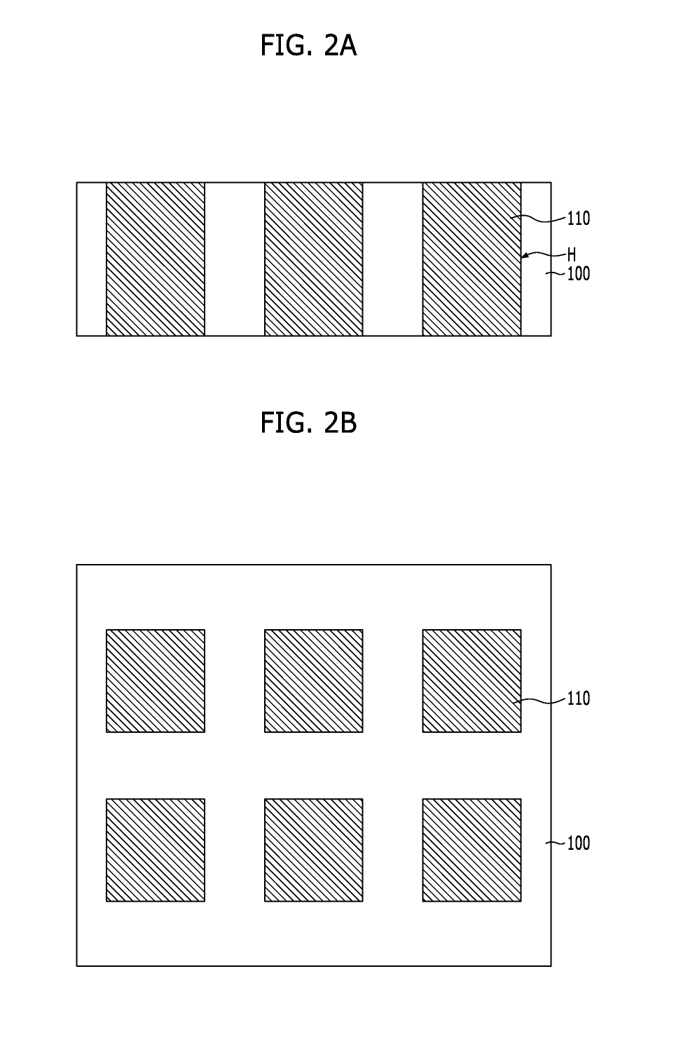

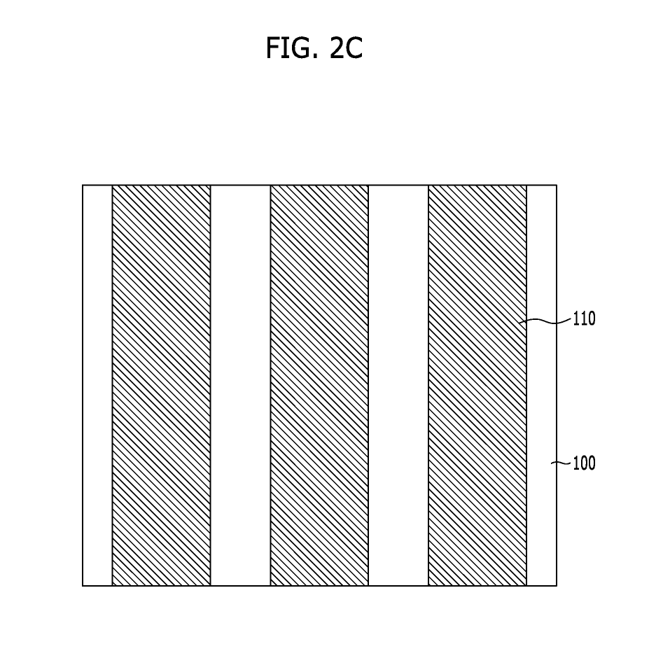

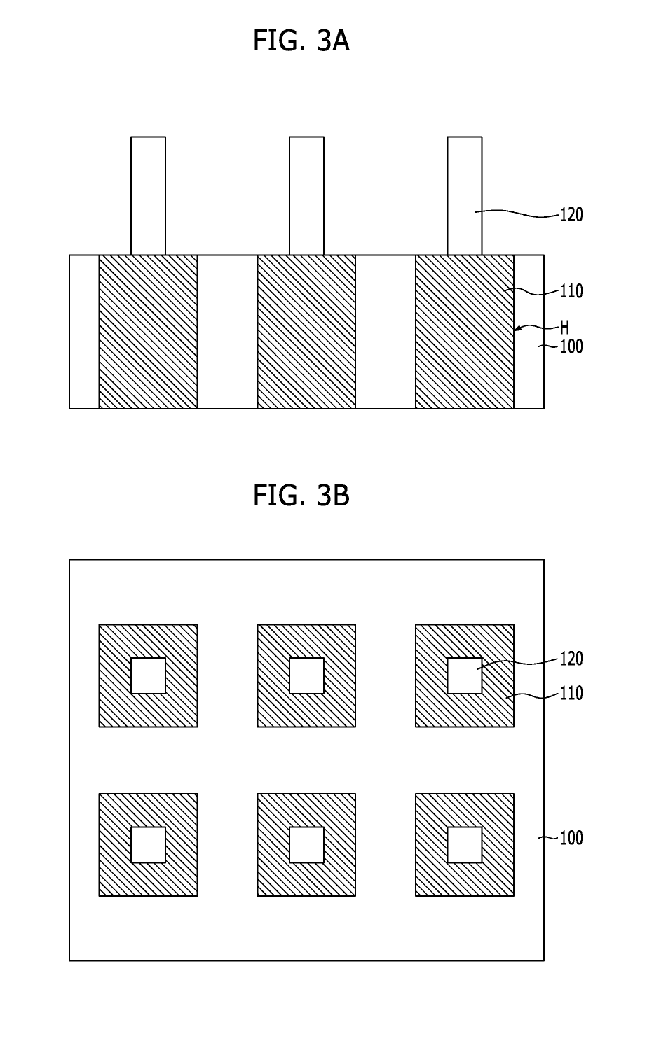

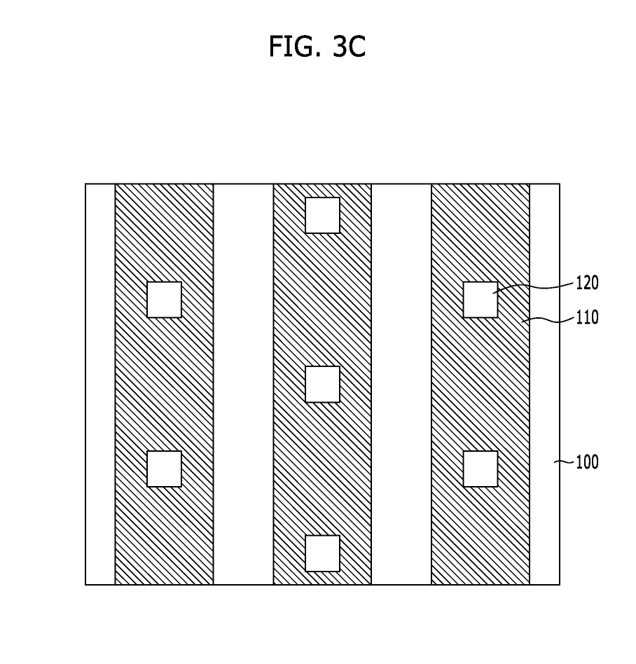

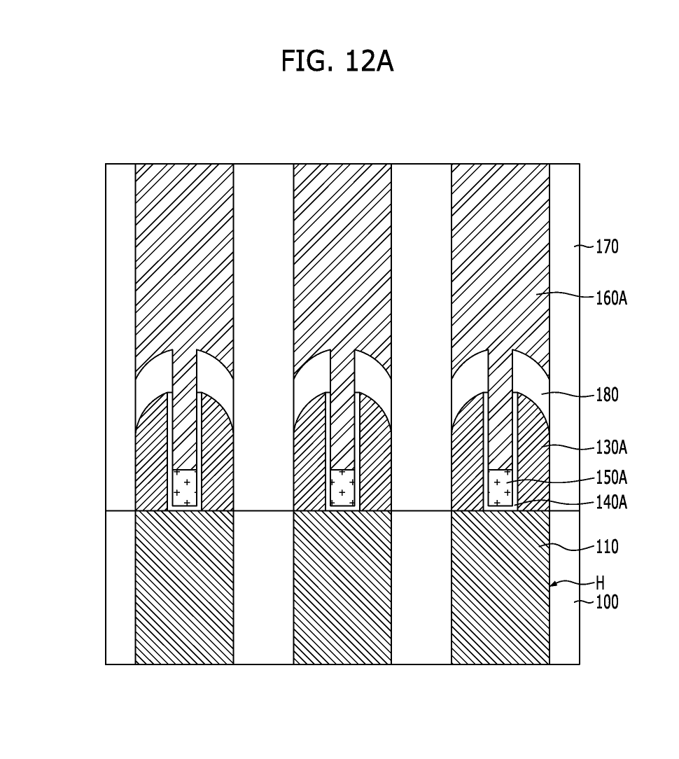

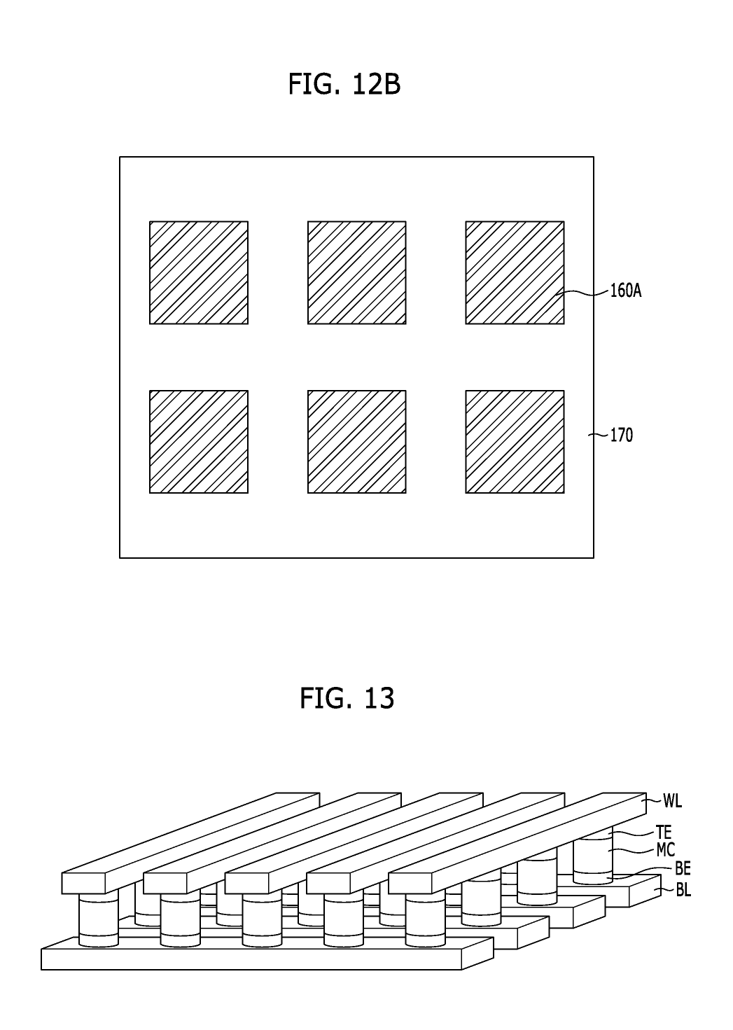

FIGS. 2A to 12B illustrate a resistance variable memory device according to an embodiment and a method for forming the resistance variable memory device. Specifically, FIGS. 12A and 12B show a resistance variable memory device according to an embodiment of the present invention, and FIGS. 2A-11B illustrate a method for forming the device shown in FIGS. 12A and 12B. Each of figures denoted with ‘A’ such as FIG. 2A, FIG. 3A, etc. shows a cross-sectional view taken along a line perpendicular to an upper surface of a substrate, and Figures denoted with ‘B’ or ‘C’ are top views showing layouts.

Referring to FIGS. 2A-2C, a first insulating layer 100 is formed over a substrate (not shown) including an underlying structure (not shown). The first insulating layer 100 may include a low dielectric (Low-k) material and/or an oxide-based material such as silicon oxide (SiO2), Boron Silicate Glass (BSG), Phosphorus Silicate Glass (PSG), Boron Phosphorus Silicate Glass (BPSG), Fluorinated Silicate Glass (FSG), Tetra Ethyl Ortho Silicate (TEOS), Spin On Glass (SOG), etc. Peripheral circuits to drive the resistance viable memory device can be formed over the substrate.

The first insulating layer 100 is selectively etched to form a hole (H) passing through the first insulating layer 100. When viewed from the top, a plurality of holes (H) may be arranged in matrix. In FIG. 2B, the hole (H) is formed in a square shape. However, the hole (H) is not limited to such a shape and can be formed in other shapes, such as rectangular, circle, oval, etc. The hole also can be formed in a line type as shown in FIG. 2C.

A first electrode 110 is formed in the hole (H). The first electrode 110 may include a conductive material. The conductive material includes any of (i) a metal nitride such as TiN, TaN, WN, etc., (ii) a metal such as W, Al, Cu, Au, Ag, Pt, Ni, Cr, Co, Ti, Ru, Hf, Zr etc., and/or (iii) doped silicon. Specifically, the conductive material is deposited to fill the hole (H) and then be subjected to a chemical mechanical polishing (CMP) process until an upper surface of the first insulating layer 100 is exposed. As a result, the first electrode 110 is formed.

Referring to FIGS. 3A-3C, a sacrificial pattern 120 is formed over the first electrode 110. The sacrificial pattern 120 may include a material with a difference in an etching selectivity from a spacer insulating layer which will be illustrated later. For example, the sacrificial pattern 120 may include polysilicon or carbon. The sacrificial pattern 120 may be formed in a pillar type which has a width narrower than that of the first electrode 110, as discussed below.

A sacrificial layer (not shown) is formed over the substrate including the first electrode 110. The sacrificial layer (not shown) may be etched using (i) an etching mask in an island type and/or (ii) a combination of a first etching mask having a line pattern extending in a first direction and a second etching mask having a line pattern extending in a second direction across the first direction. In order to obtain a fine pattern, a spacer patterning technology (SPT) may be employed in etching the sacrificial layer (not shown). As a result, the sacrificial pattern 120 which vertically extends from a surface of the first electrode 110 is formed.

In FIG. 3B, the sacrificial pattern 120 is in a square shape but not limited to such shape. The sacrificial pattern 120 may be formed in a various shapes such as rectangular, circle, oval, etc. Alternatively, as shown in FIG. 3C, a plurality of sacrificial patterns 120 can be arranged in a diagonal direction with respect to a direction along which the first electrode 110 extends to increase a space between neighboring memory cells, reducing interference between the neighboring memory cells.

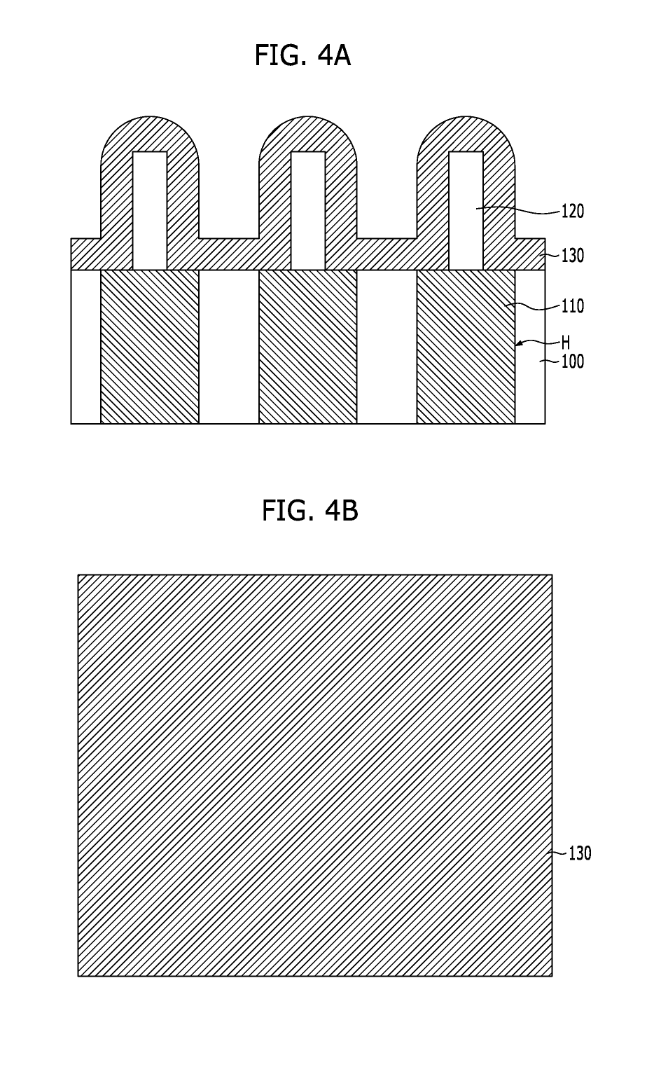

Referring to FIGS. 4A and 4B, a spacer insulating layer 130 is deposited over the resultant including the sacrificial pattern 120. The spacer insulating layer 130 will form a spacer over a sidewall of the sacrificial pattern 120 in a subsequent process. The spacer insulating layer 130 may be formed in a conformal manner (or in a lining pattern) along a contour of the sacrificial pattern 120 using a material having a difference in an etching selectivity from a material forming of the sacrificial pattern 120.

For example, when the sacrificial pattern 120 is formed of polysilicon, the spacer insulating layer 130 may be formed of silicon nitride. Alternatively, when the sacrificial pattern 120 is formed of carbon, the spacer insulating layer 130 may be formed of ultra-low temperature oxide (ULTO).

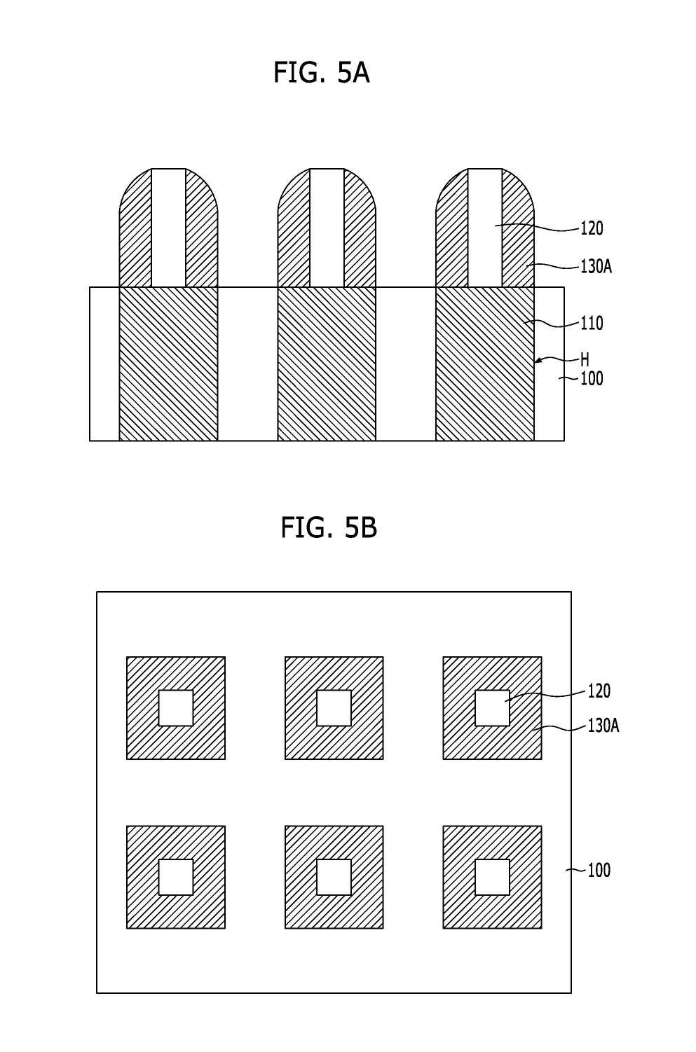

Referring to FIGS. 5A and 5B, the spacer insulating layer 130 is etched anisotropically to form a spacer 130A surrounding sidewalls of the sacrificial pattern 120. The spacer insulating layer 130 is etched until an upper surface of the sacrificial pattern 120 is exposed to form the spacer 130A. In FIG. 5A, an external boundary of the spacer 130A coincides with an external boundary of the first electrode 110. However, configuration of the spacer 130A is not limited thereto and may be formed wider or narrower than that shown in FIG. 5A.

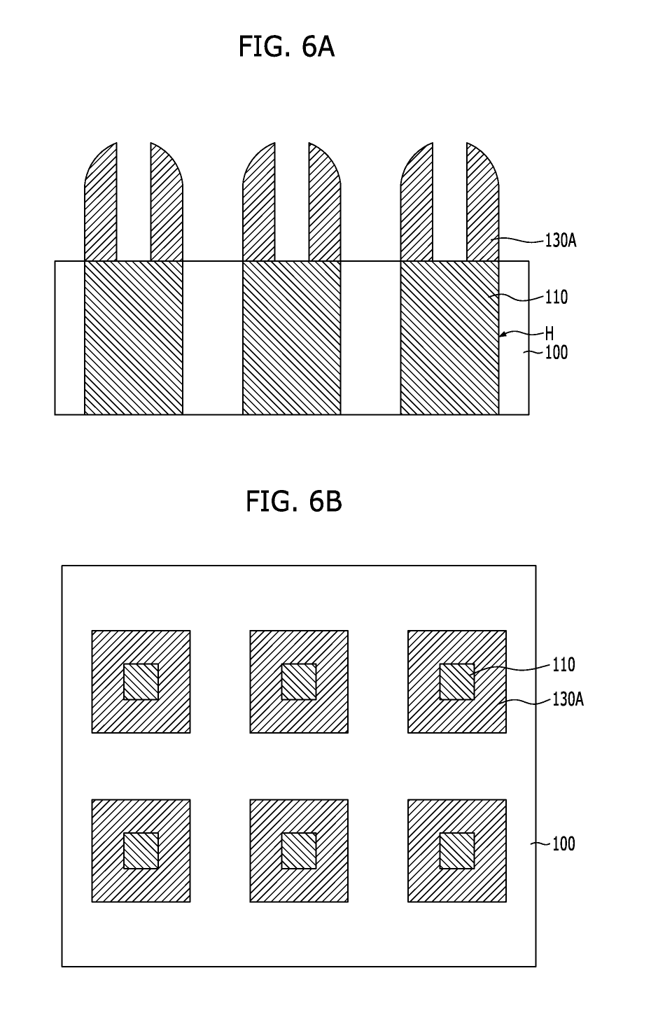

Referring to FIGS. 6A and 6B, the sacrificial pattern 120 which is exposed by the spacer 130A is removed. The sacrificial pattern 120 may be removed by an etch-back process using a difference in an etch selectivity from the spacer 130A. As a result, an upper surface of the first electrode 110 is exposed.

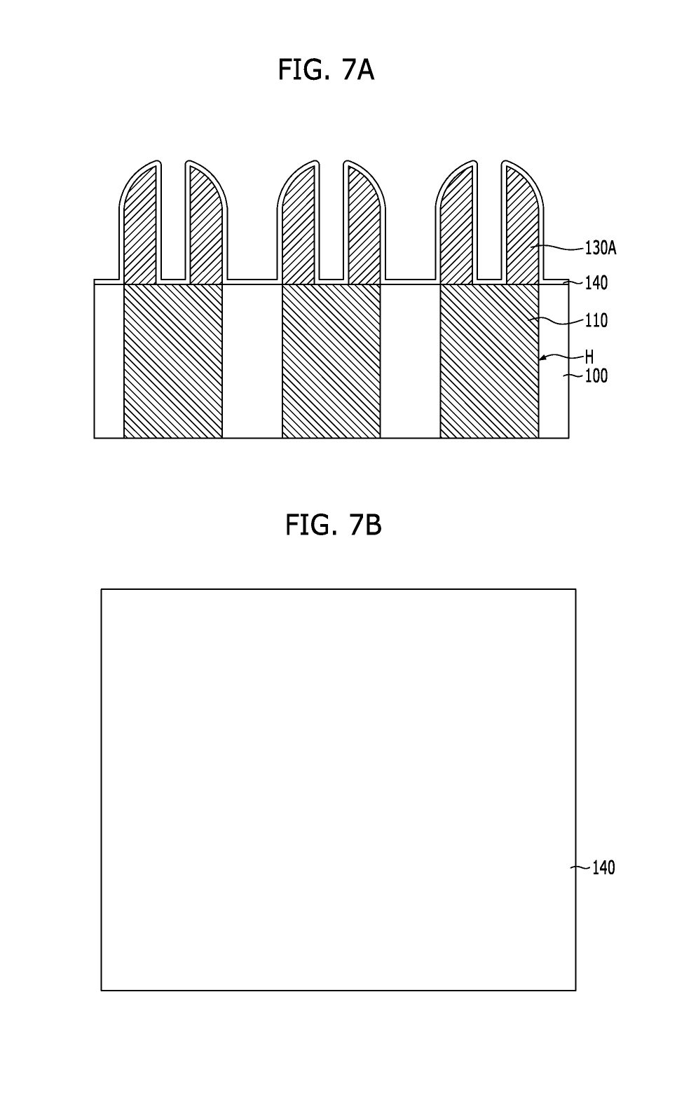

Referring to FIGS. 7A and 7B, a first resistance variable layer 140 is formed over the resultant where the sacrificial pattern 120 is removed. The first resistance variable layer 140 includes a material whose electrical resistance varies depending on factors such as a change in oxygen vacancies, ion migration, and/or a phase change. The first resistance variable layer 140 may be formed in a conformal manner (or in a lining pattern) using an atomic layer deposition (ALD) or chemical vapor deposition (CVD).

Examples of materials whose electrical resistance varies depending on a change in oxygen vacancies or ion migration include but are not limited to (i) Perovskite material such as STO (SrTiO3), BTO (BaTiO3), PCMO (Pr1-xCaxMnO3), etc., (ii) oxide material such as titanium oxide (TiO2, Ti4O7, etc.), hafnium oxide (HfO2), zirconium oxide (ZrO2), aluminum oxide (Al2O3), tantalum oxide (Ta2O5), niobium oxide (Nb2O5), cobalt oxide (Co3O4), nickel oxide (NiO), tungsten oxide (WO3), transition metal oxide (TMO) such as lanthanum oxide (La2O3), etc.

A material whose electrical resistance varies depending on a phase change, can include but is not limited to a Chalcogenide material such as GeSbTe (GTS) in which germanium, antimony, and tellurium are present at a given ratio. Such material is interchangeable between a crystalline structure and an amorphous structure depending on temperature. The first resistance variable layer 140 may be omitted.

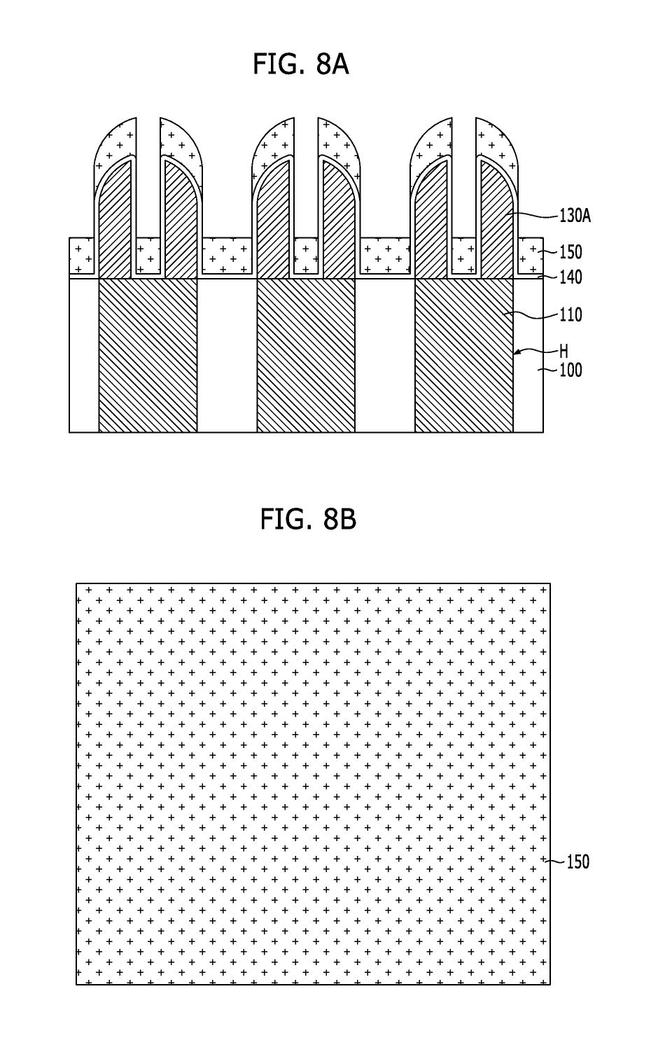

Referring to FIGS. 8A and 8B, a second resistance variable layer 150 is formed over the first resistance variable layer 140. The second resistance variable layer 150 may include a material whose electrical resistance varies depending on a change in oxygen vacancies, ion migration, and/or a phase change. For example, the second resistance variable layer 150 may include a transition metal oxide (TMO), a Perovskite material, or a Chalcogenide material and may be formed by a physical vapor deposition (PVD) employing a highly directional plasma (HDP). In this particular embodiment, the second resistance variable layer 150 is formed in self-aligned manner on the inside of spacers 130A. In other words, the second resistance variable layer 150 need not be subject to an etching process. Thus, the second resistance variable layer 150, especially its sidewalls, can be protected from being damaged in the course of subsequent etching process.

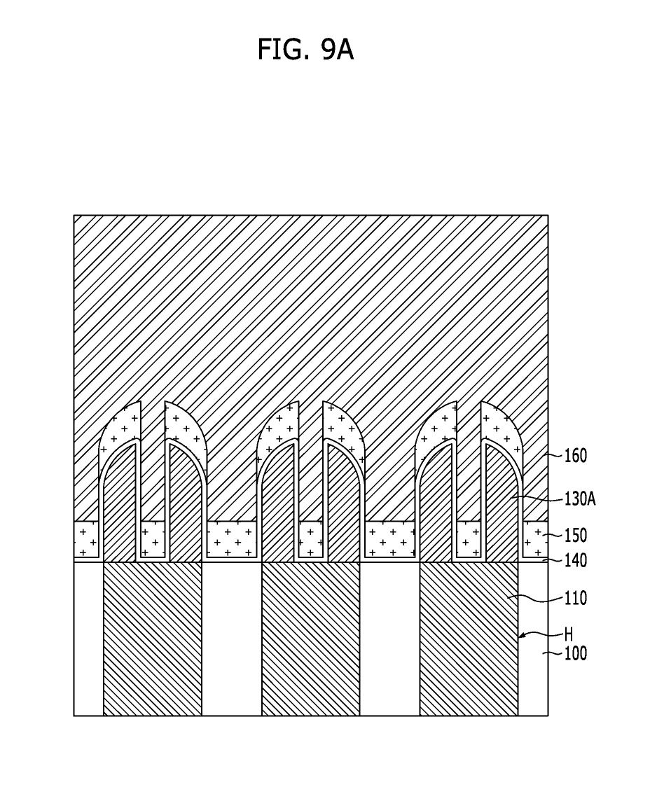

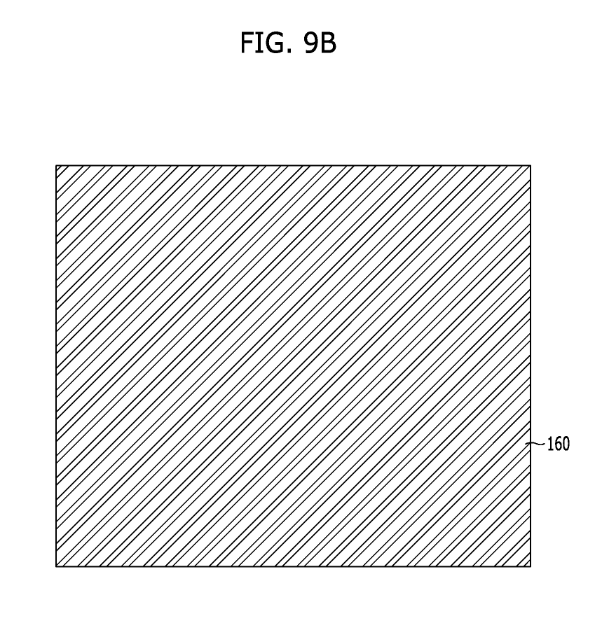

Referring to FIGS. 9A and 9B, a second electrode layer 160 is formed over the second resistance variable layer 150. The second electrode 160 may include a conductive material such as a metal nitride, a metal, or a doped polysilicon and may be the same material as the first electrode 110.

The second electrode layer 160 is formed over the second resistance variable layer 150 in a self-aligned manner by being deposited between the spacers 130A. Thus, the second electrode layer 160 can be formed in a critical dimension (size) as small as a critical dimension of the second resistance variable layer 150 without additionally patterning the second electrode layer 160 at a critical dimension level as same as that of the second resistance variable layer 150. In other words, the second electrode layer 160 can be formed as small in size as the second resistance variable layer 150 without being subject to an additional patterning process.

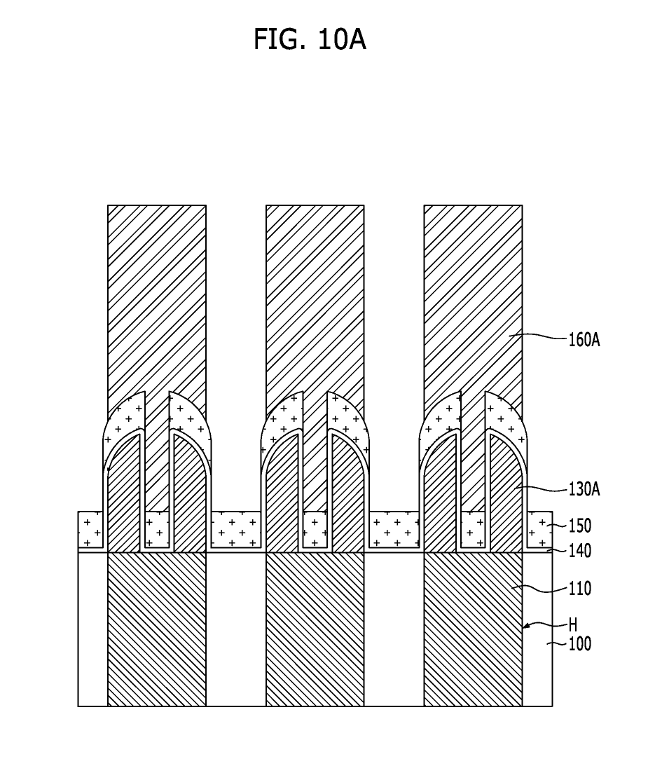

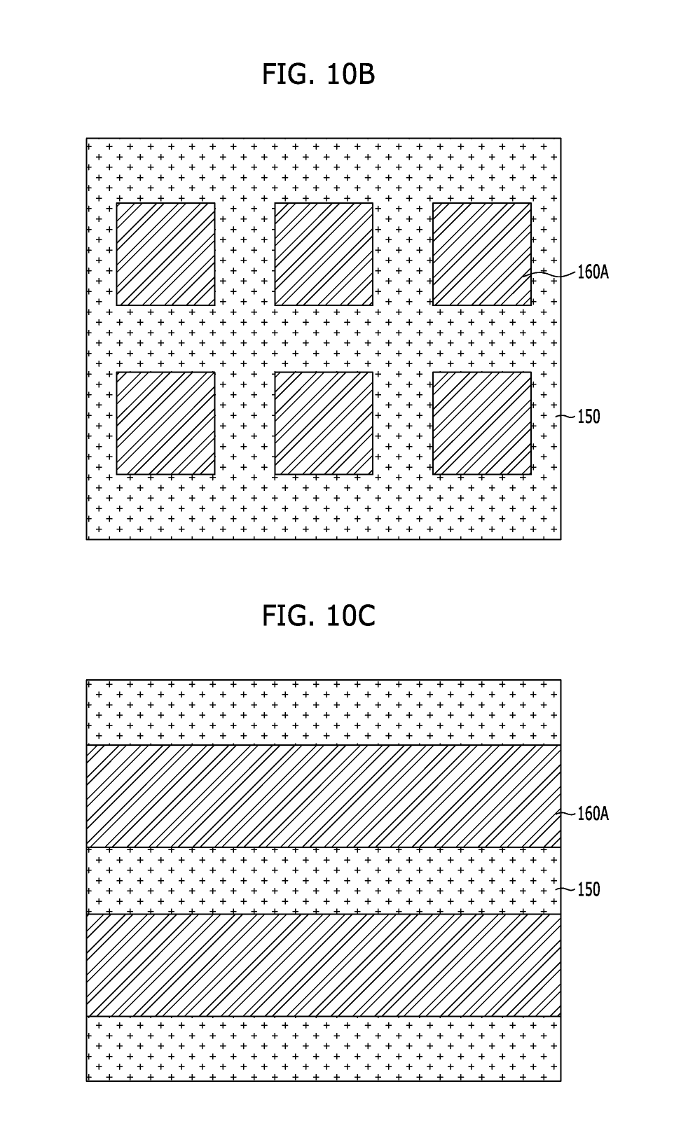

Referring to FIGS. 10A to 10C, the second electrode 160 is selectively etched to form a second electrode 160A. In the process of forming the second electrode 160A, the second electrode layer 160 may be subject to an anisotropic etching process and selectively removed. Upon the selective removal, the second electrode 160A is configured to expose at least partially the second resistance variable layer 150 between the spacer 130A and the second electrode 160A. As a result, portions of the first and the second resistance variable layers 140, 150 may be exposed. The second electrode 160A may be formed over the first electrode 110. In an embodiment, when viewed from a top, a plurality of second electrodes 160A may be arranged in a matrix. In FIG. 10B, when viewed from a top, the second electrode 160A is shown in a square shape but is not limited to such shape.

The second electrode 160A may be rectangular, circle, oval, etc. in shape. Alternatively, the second electrode 160A may be a line extending along a given direction, as shown in FIG. 10C.

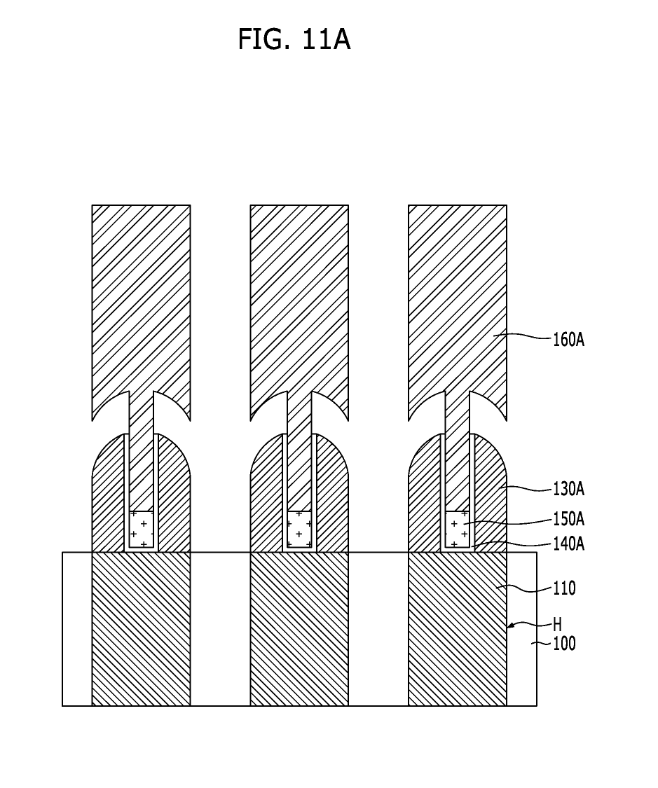

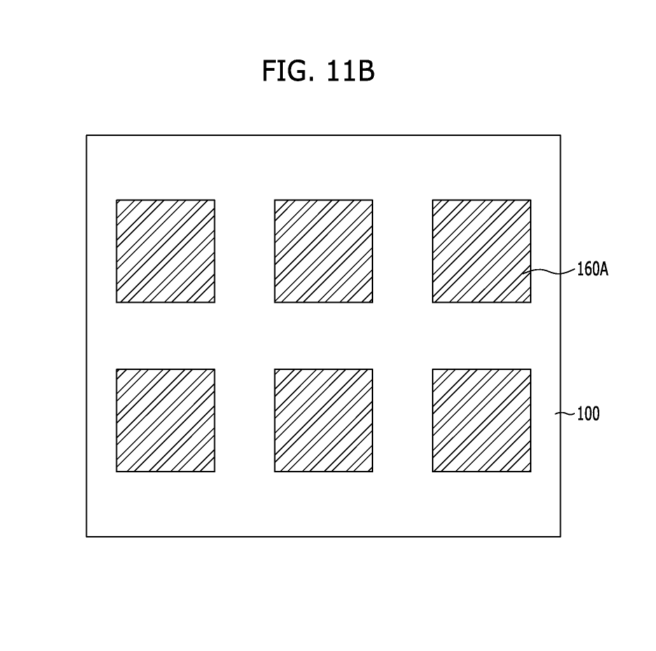

Referring to FIGS. 11A and 11B, the first and the second resistance variable layers 140, 150 exposed by the second electrode 160A are removed. However, the portion of the first and the second resistance variable layers 140, 150 which are located inside the spacers 130A and covered by the second electrode 160A, remain.

In order to remove the exposed first and second resistance variable layers 140, 150, a wet etching process such as a dip-out may be used. The first and the second resistance variable layers 140, 150 inside the spacers 130A and over the first electrode 110 are not vulnerable to the wet etching process because they are covered by the second electrode 160A.

Hereinafter, the first resistance variable layer 140 and the second resistance variable layer 150 remaining between the spacers 130A are referred to as first and second resistance variable patterns 140A, 150A, respectively.

Referring to FIGS. 12A and 12B, a second insulating layer 170 is formed to fill a space between the second electrodes 160A. The second insulating layer 170 may include a low dielectric material or an oxide, for example, silicon oxide, BSG, PSG, BPSG, FSG, TEOS, SOG, etc.

Since an upper portion of the second electrode 160A is formed wider than a lower portion of the second electrode 160A, an air gap 180 may be formed between the second electrode 160A and the spacer 130A by a shadowing effect. According to certain embodiments, the air gap 180 may be replaced with an insulating pattern, for example, by filling a space between the second electrode 160A and the spacer 130A which is created by removing the second resistance variable layer 150 using the second electrode 160A as a mask.

According to the method mentioned above, a resistance variable memory device, shown in FIGS. 12A and 12B, according to an embodiment may be formed.

Referring to FIGS. 12A and 12B, the resistance variable memory device according to an embodiment includes a first electrode 110, a second electrode 160A spaced apart from the first electrode 110, a first resistance variable pattern 140A located over the first electrode 110 and surrounding a lower portion of the second electrode 160A, a second resistance variable pattern 150A provided between the first resistance variable pattern 140A and the second electrode 160A, a spacer 130A surrounding a sidewall of the first resistance variable pattern 140A, and an air gap 180 formed over the spacer 130A.

The air gap 180 may surround a portion of a sidewall of the second electrode 160A. An upper portion of the second electrode 160A which is located above the air gap 180 may be formed wider than a lower portion of the second electrode 160A. For example, assuming that a width of the first electrode 110 is D1 and the upper portion of the second electrode 160A is D2. D1 and D2 may be substantially the same. The lower portion of the second electrode 160A may have a width D3 which is narrower than D2. The second resistance variable pattern 150A may be a width D4 which is narrower than D2. The width D4 may be substantially the same as the width D3. The spacer 130A surrounding the second resistance variable pattern 150A may have a width D5 which is narrower than D2. The first resistance variable pattern 140A may have a width D6 which is narrower than D2. D2 may be substantially the same as a sum of D4, D5×2, and D6×2, that is, D2≈D4+(D5×2)+(D6×2).

Each of the first and the second resistance variable patterns 140A, 150A may include a material whose electrical resistance changes depending on a change in oxygen vacancies, ion migration, or a phase change. The first resistance variable pattern 140A may be formed in a cylinder type.

The first and the second electrodes 110, 160A may extend in directions crossing each other. When neighboring memory cells are arranged in a diagonal direction with respect to a direction in which the first electrode 110 extends, the first and the second electrodes 110, 160A may cross with an acute angle rather than a right angle.

In summary, assuming that the first resistance variable pattern 140A is omitted, the second resistance variable pattern 150A may be formed between the first and the second electrodes 110, 160A. Sidewalls of the second resistance variable pattern 150A may be surrounded by the spacer 130A. The spacer 130A may extend upward to surround the lower portion of the second electrode 160A. The air gap 180 (or an alternative insulating pattern) may be formed between the spacer 130A and the upper portion of the second electrode 160A.

In the case that the first resistance variable pattern 140A is formed, the first resistance variable pattern 140A may be formed (i) between the first electrode 110 and the second resistance variable pattern 150A and (ii) between the sidewall of the second resistance variable pattern 150A and the spacer 130A. The first resistance variable pattern 140A may extend between the lower portion of the second electrode 160A and the spacer 130A.

FIG. 13 is a perspective view showing a cross point cell array.

Referring to FIG. 13, a resistance variable memory cell device according to an embodiment may be configured in a cross point cell array. Under a cross point cell array structure, memory cells are provided at points where a plurality of bit lines (BL) in parallel to each other intersects with a plurality of word lines (WL) in parallel to each other. An optional element (not shown) such as a transistor or a diode may be coupled to an upper portion of a lower portion of each memory cell.

The memory cell (MC) may include a resistance variable pattern whose resistance varies between at least two different resistance states depending on voltage or current applied to the memory cell. A lower portion of each memory cell may be coupled to a bit line through a lower electrode (BE) and an upper portion may be coupled to a word line through an upper electrode (TE).

In FIG. 13, the memory cell (MC) has a single-layered configuration, but this is not required and other embodiments may not be limited to such a configuration. The memory cell may be stacked with multiple layers by repeatedly performing the process mentioned above to increase a degree of integration of a resistance variable memory device.

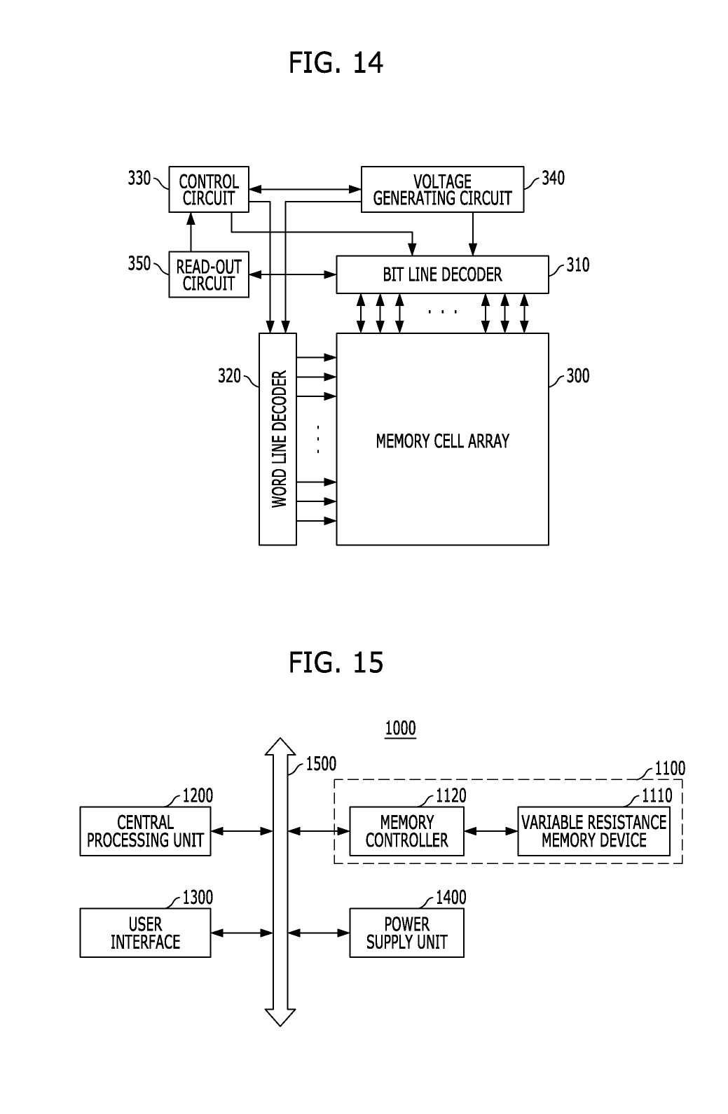

FIG. 14 is a block diagram showing a resistance variable memory device according to an embodiment.

Referring to FIG. 14, resistance variable memory cells (MC) according to an embodiment of the present invention are arranged in matrix to form a memory cell array 300. A bit line decoder 310, a word line decoder 320, a control circuit 330, a voltage generating circuit 340, and a read-out circuit 350 may be provided in a peripheral region.

The bit line decoder 310 is coupled to bit lines of the memory cell array 300, and selects a bit line in response to an address signal. Likewise, the word line decoder 320 is coupled to word lines of the memory cell array 300 and selects a word line (WL) in response to an address signal.

Thus, a specific memory cell (MC) in the memory cell array 300 is selected by the bit line decoder 310 and the word line decoder 320.

The control circuit 330 controls the bit line decoder 310, the word line decoder 320, and the voltage generating circuit 340 based on an address signal, a control input signal, and a data-writing input. Especially, the control circuit 330 controls writing, deleting, and reading operations of the memory cell array 300.

The control circuit 330 may perform as an address buffer circuit, a data input/output buffer circuit, or a control input buffer circuit.

The voltage generating circuit 340 generates voltage necessary for performing writing, deleting, or reading operation for the memory cell array 300 and provides the generated voltage to the bit lines (BL) and the word lines (WL). The read-out circuit 350 detects resistance of a selected memory cell, detects data stored in the selected cell, and transfers the detected data to the control circuit 330.

FIG. 15 a block diagram of an information processing system employing a resistance variable memory device according to an embodiment.

Referring to FIG. 15, an information processing system employing a resistance variable memory device according to an embodiment includes a memory system 1100, a central processing unit 1200, a user interface 1300, and a power supply unit 1400, and these units may communicate data with each other through a bus 1500.

The memory system 1100 includes a resistance variable memory device 1110 and a memory controller 1120. The resistance variable memory device 1110 may store data processed through the central processing unit 1200 or external data input through the user interface 1300.

The information processing system 1000 may be employed for any data storage device, for example, a memory card, a solid state disk (SSD), or a mobile device such as a smart phone.

As described above, according to an embodiment of a resistance variable memory cell device and a method for forming the device, a sidewall of a resistance variable pattern can be protected from being damaged in an etching process and thus reliability of the resistance variable memory cell device can be improved.

In addition, the first resistance variable pattern surrounding the second resistance variable pattern may be provided between the second resistance variable pattern and the spacer. An air gap formed between the upper portion of the second electrode and the spacer may reduce parasitic capacitance between electrodes, improving an operational speed of a resistance variable memory device.

Although various embodiments have been described for illustrative purposes, it will be apparent to those skilled in the art that various changes and modifications may be made without departing from the spirit and scope of the invention as defined in the following claims.

What is claimed is:

1. A resistance variable memory device comprising:
a first electrode;
a second electrode spaced apart from the first electrode;
a first resistance variable pattern provided over the first electrode and surrounding a lower portion of the second electrode; and
a spacer surrounding a sidewall of the first resistance variable pattern.

2. The resistance variable memory device of claim 1, the device further comprising:
a second resistance variable pattern provided between the first resistance variable pattern and the second electrode.

3. The resistance variable memory device of claim 1, the device further comprising:
an air gap formed over the spacer.

4. The resistance variable memory device of claim 3,
wherein the air gap surrounds a portion of a sidewall of the second electrode.

5. The resistance variable memory device of claim 3,
wherein the second electrode includes an upper portion provided over the air gap and the lower portion provided below the air gap, and
wherein the upper portion of the second electrode is wider than the lower portion of the second electrode.

6. The resistance variable memory device of claim 1,
wherein the first resistance variable pattern includes material whose electrical resistance changes depending on a change in oxygen vacancies, ion migration, or a phase change.

7. The resistance variable memory device of claim 1,
wherein the first resistance variable pattern is formed in a cylinder shape.

8. The resistance variable memory device of claim 1,
wherein the first electrode and the second electrode extend in directions crossing each other.

9. The resistance variable memory device of claim 8,
wherein the first and the second electrodes cross each other at an angle other than a right angle.

10. A resistance variable memory device comprising:
a first electrode;
a second electrode spaced apart from the first electrode;
a first resistance variable pattern provided over the first electrode and surrounding a lower portion of the second electrode; and
an air gap surrounding a portion of a sidewall of the second electrode.

11. The resistance variable memory device of claim 10, the device further comprising:
a second resistance variable pattern provided between the first resistance variable pattern and the second electrode.

12. The resistance variable memory device of claim 10,
wherein the second electrode includes an upper portion provided over the air gap and the lower portion provided below the air gap, and
wherein the upper portion of the second electrode is wider than the lower portion of the second electrode.

13. The resistance variable memory device of claim 10,
wherein the first resistance variable pattern includes material whose electrical resistance changes depending on a change in oxygen vacancies, ion migration, or a phase change.

14. The resistance variable memory device of claim 10,
wherein the first resistance variable pattern is formed in a cylinder shape.

15. The resistance variable memory device of claim 10,
wherein the first electrode and the second electrode cross each other.

16. The resistance variable memory device of claim 15,
wherein the first and the second electrodes cross each other at an angle other than a right angle.

17. A resistance variable memory device comprising:
a first electrode having a first width D1;
a second electrode spaced from the first electrode and including a lower portion having a second width D2 and an upper portion having a third width D3; and
a first resistance variable layer and a spacer interposed between the first and the second electrode,
wherein the spacer is provided over an outer sidewall of the first resistance variable layer, and
wherein the lower portion of the second electrode extends down over an inner sidewall of the spacer to be coupled to the first resistance variable layer.
